(19) United States
(12) Patent Application Publication
(10) Pub. No.: US 2003/0048655 A1
(43) Pub. Date: Mar. 13, 2003

(54) Semiconductor memory cell with leakage current compensation using a tunnel diode

(76) Inventors: El-Badawy Amien El-Sharawy, Gilbert, AZ (US); Graham Leitch Clark, Fountain Hills, AZ (US)

Correspondence Address: Lowell W. Gresham, MESCHKOW & GRESHAM, P.L.C., 5727 N. Seventh Street, Suite 409, Phoenix, AZ, 85014, US

(21) Appl. No.: 09/951,801

(22) Filed: Sep. 10, 2001

(51) Int. Cl. G11C 11/24

(52) U.S. Cl. 365/149

(57) ABSTRACT

A memory cell (10) includes a transistor (12), a storage capacitor (14) and a tunnel diode (16). The transistor (12), storage capacitor (14) and tunnel diode (16) couple together at a cell state node (28). When the transistor (12) in the off state, leakage current from cell state node (28) is compensated by current supplied by the tunnel diode (16). The tunnel diode (16) is formed on a node (26) of the transistor (12) so that it consumes no additional semiconductor area beyond that used by the transistor (12) and storage capacitor (14).

### TECHNICAL FIELD OF THE INVENTION

The present invention relates generally to the field of semiconductor memory. More specifically, the present invention relates to semiconductor read/write memory cells in which memory states are represented by charges stored in capacitors within the memory cells, e.g., dynamic memory.

### BACKGROUND OF THE INVENTION

Non-volatile memory retains stored data even when power is off. When power is restored, data that was stored in the non-volatile memory when last energized is still available. Conventional examples of non-volatile read/write semiconductor memory include EPROM, EEPROM, and Flash Memory. Volatile memory does not retain stored data when power is off. Thus, any data stored in a volatile memory when power goes off is lost. Conventional examples of volatile read/write semiconductor memory include static random access memory (SRAM) and dynamic random access memory (DRAM).

While non-volatile semiconductor memory has some significant advantages over volatile semiconductor memory, it is typically used only in limited specialized applications because it nevertheless suffers from serious drawbacks. Some of its drawbacks include a large semiconductor area per bit requirement (i.e., low bit density), slow write operations, and only a limited number of write operations may be possible over the lifetime of the memory. Compared to non-volatile memory, volatile memory typically stores more data per device thereby significantly lowering costs, performs write operations faster, and performs a virtually unlimited number of write operations.

A conventional SRAM represents memory states using bistable semiconductor circuits, such as cross-coupled transistors. So long as power remains applied, data is indefinitely retained in such bistable semiconductor circuits. A conventional DRAM represents memory states as electrical charges stored in capacitors. However, the capacitors tend to leak and gradually lose their charges over time. Consequently, conventional DRAM memory devices include control circuitry to perform refresh operations from time to time. During a refresh operation, data from certain memory cells is read and rewritten to refresh the charge in the cell's capacitors.

SRAM can be configured to have faster throughput times and to operate at lower power consumption levels than DRAM, due in large part to the overhead of DRAM's refresh operations. However, in spite of significant SRAM advantages, DRAM has nevertheless achieved tremendous commercial success in computer and other electronic designs. The success of DRAM and corresponding limited applicability of SRAM is due, at least in part, to bit storage density. A typical SRAM memory cell requires semiconductor area for six transistors while a typical DRAM memory cell requires semiconductor area only for a single transistor and a capacitor. Consequently, a significantly greater amount of data may be stored per DRAM device than per SRAM device of equivalent semiconductor die area and cost.

As semiconductor processing techniques have permitted the formation of smaller and smaller semiconductor structures, memory cell sizes have shrunk. While the shrinkage of a DRAM memory cell transistor directly follows from smaller semiconductor processing resolution, a DRAM memory cell capacitor cannot simply shrink proportionally. A certain amount of capacitance is required to store sufficient charge to drive a “bit” line connected to a sense amplifier, and as memories become larger with shrinking semiconductor processing resolution, the “bit” lines tend to be loaded by more memory cells.

The memory cell capacitor is conventionally formed as a structure having a dielectric region sandwiched between two conductive areas. The smaller the area, the thicker the dielectric region, or the lower the dielectric constant of the dielectric region, the smaller the resulting capacitance. As memory cell size shrinks, capacitor area likewise shrinks. The dielectric region thickness is difficult to shrink while maintaining sufficient safeguards against shorting between the conductive areas. Accordingly, in order for the memory cell capacitor to continue to exhibit a usable amount of capacitance, more exotic materials have been used which exhibit higher dielectric constants.

Past memory cell designs often used a memory cell capacitor dielectric formed substantially of SiO₂, which exhibits a dielectric constant less than 10 but desirably exhibits a very low leakage current. More recent higher density memory cell designs use dielectric materials having dielectric constants greater than 10. Unfortunately these materials exhibit greater leakage. The greater leakage forces the memory device to engage in an undesirably high number of refresh operations. Refresh operations are undesirable because they cause the memory device to consume an excessive amount of power and slow memory throughput.

In order to ameliorate the undesirably large leakage currents exhibited by conventional memory devices having memory cell capacitor dielectric materials with dielectric constants greater than 10, heroic processing efforts are conventionally taken, which typically have counterproductive side effects. For example, high temperature treatments conducted in an oxygen atmosphere may lessen leakage, but concurrently lessen capacitance too. Other techniques may lessen leakage, but increase resistance so that the RC time constants associated with reading and writing are lengthened and access times suffer.

Accordingly, a need exists for a dynamic semiconductor memory cell that has little or no need for refresh operations.

### SUMMARY OF THE INVENTION

It is an advantage of the present invention that an improved semiconductor memory with leakage current compensation is provided.

Another advantage of the present invention is that an improved semiconductor memory is provided which achieves the bit densities of DRAM, but requires little or no refreshing.

Another advantage of the present invention is that an improved dynamic semiconductor memory is provided that requires little or no refreshing and therefore consumes less power and has reduced throughput times.

Another advantage of the present invention is that a tunnel diode is provided in a memory cell to supply current lost by leakage.

Another advantage of the present invention is that a tunnel diode is provided in a memory cell using substantially the same semiconductor die area that is used in forming a memory cell transistor and storage capacitor.

Another advantage of the present invention is that an improved semiconductor memory with leakage current compensation is provided which can be fabricated using routine processing activities in widespread use throughout the semiconductor industry.

Another advantage of the present invention is that an improved semiconductor memory with leakage current compensation is provided which readily accommodates capacitors formed using materials having dielectric constants greater than 10, and which reduces counterproductive processing techniques previously performed to lessen leakage.

These and other advantages are realized in one form by an improved semiconductor memory cell with leakage current compensation. The semiconductor memory cell includes a transistor, a storage capacitor coupled to the transistor, and a tunnel diode coupled to the transistor and storage capacitor. Leakage current of the storage capacitor is compensated by current from said tunnel diode.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, and:

FIG. 1 shows a schematic circuit diagram of a memory cell configured in accordance with a preferred embodiment of the present invention;

FIG. 2 shows a graph of an exemplary transfer function exhibited by a tunnel diode included in the memory cell depicted in FIG. 1; and

FIG. 3 shows a cross sectional schematic view of a selected portion of the memory cell depicted in FIG. 1.

### DETAILED DESCRIPTION OF THE PREFERRED EMBODIMENTS

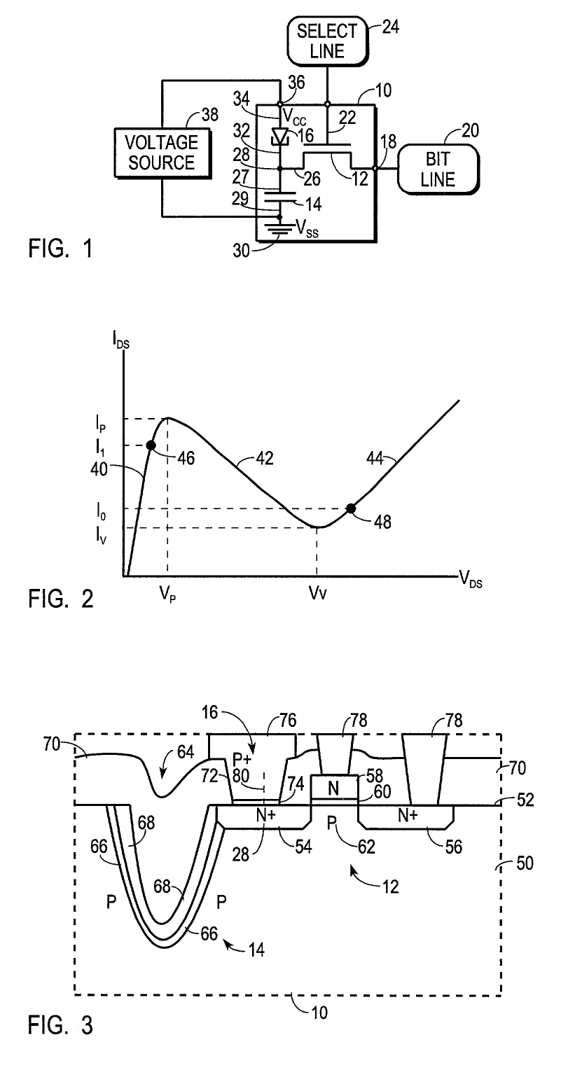

FIG. 1 shows a schematic circuit diagram of a volatile, dynamic memory cell 10 configured in accordance with a preferred embodiment of the present invention. In accordance with one embodiment of the present invention, memory cell 10 is a refreshless dynamic memory cell. In other words, memory cell 10 may be configured so that no refresh operations are required in order for data stored in memory cell 10 to be retained for as long as memory cell 10 remains energized. In a typical application, memory cell 10 is formed on a semiconductor substrate (discussed below) with a multiplicity, typically in the millions, of other memory cells 10 and with various control circuits (not shown) conventional in the art of dynamic memories. However, control circuits dedicated to performing refresh operations in conventional dynamic memories may be omitted in one preferred embodiment of the present invention.

Memory cell 10 includes a transistor 12, a storage capacitor 14, and a tunnel diode 16. An input/output (I/O) node 18, e.g., a drain node, of transistor 12 couples to a bit line 20 that couples memory cell 10 to other memory cells 10 and to circuitry that controls reading a bit of data from and writing a bit of data to memory cell 10. A control node 22, e.g., a gate node, of transistor 12 couples to a select line 24 that is driven by control circuitry. Select line 24 activates when a read and/or write access operation is to be performed on memory cell 10. Transistor 12 exhibits an on state when select line 24 is activated. Otherwise, transistor 12 exhibits an off state. Bit line 20 and select line 24 are desirably operated in a substantially conventional DRAM manner, except that in one preferred embodiment no provisions are needed for refreshing memory cell 10.

An I/O node 26, e.g., a source node, of transistor 12 corresponds to a cell state node 28 of memory cell 10. Cell state node 28 indicates the memory state of memory cell 10. When cell state node 28 is at a relatively high voltage, then a first memory state, such as a logic one, is indicated. When cell state node 28 is at a relatively low voltage, then a second memory state, such as a logic zero, is indicated.

A first port 27 of storage capacitor 14 couples to cell state node 28, and a second port 29 of storage capacitor 14 couples to a reference voltage node 30 labeled V_{SS} in FIG. 1. A port 32, e.g., a cathode, of tunnel diode 16 couples to cell state node 28, and a port 34, e.g., an anode, of tunnel diode 16 couples to a reference voltage node 36 labeled V_{CC} in FIG. 1. A voltage source 38 is provided with positive and negative terminals coupled to reference voltage nodes 36 and 30, respectively. Voltage source 38 is typically not dedicated to use with only one memory cell 10. Rather, voltage source 38 is desirably regulated to provide a suitable voltage level (discussed below) between reference voltage nodes 36 and 30 of any number of memory cells 10.

FIG. 2 shows a graph of an exemplary transfer function exhibited by a tunnel diode 16. Referring to FIGS. 1 and 2, as the voltage across tunnel diode 16 increases from zero to a peak voltage V_{P}, tunnel diode 16 exhibits a positive resistance region 40 where current increases as voltage increases. As voltage continues to increase past V_{P} to a valley voltage V_{V}, tunnel diode 16 then exhibits a negative resistance region 42 where current decreases as voltage increases. As voltage continues to increase past V_{V}, tunnel diode 16 exhibits a positive resistance region 44 where current increases as voltage increases.

Positive resistance regions 40 and 44 are stable regions of operation for tunnel diode 16. However, tunnel diode 16 tends not to operate in the unstable negative resistance region 42. Rather, the voltage across tunnel diode 16 tends to snap to the positive resistance region 44 as soon as voltage increases past V_{P} or to positive resistance region 40 as soon as voltage diminishes below V_{V}.

Memory cell 10 is characterized by the leakage of electrical current from cell state node 28 when transistor 12 is in the off state. This leakage current is due primarily to leakage in storage capacitor 14, but is also due to leakage across transistor 12. In accordance with one aspect of the preferred embodiments, this leakage current is desirably greater than a minimum leakage current of I_{V}, the current transmitted by tunnel diode 16 when operating at valley voltage V_{V}, and desirably less than a maximum leakage current I_{P}, the current transmitted by tunnel diode 16 when operating at peak voltage V_{P}.

Accordingly, tunnel diode 16 and storage capacitor 14 are mutually configured so that leakage current from cell state node 28 approximately equals the current supplied through tunnel diode 16 to cell state node 28. In other words, current supplied through tunnel diode 16 compensates for the leakage current of storage capacitor 14 and for other leakage currents from cell state node 28. Since leakage current is compensated when transistor 12 is in the off state, no refresh operations are required to refresh the charge on storage capacitor 14, making dynamic memory cell 10 a refreshless dynamic memory cell 10.

When transistor 12 is in the off state and cell state node 28 is at a relatively high voltage, memory cell 10 may be characterized as indicating a logic one memory state. Tunnel diode 16 has a relatively low voltage across its ports 32 and 34, but storage capacitor 14 is storing a relatively high charge. Tunnel diode 16 operates in positive resistance region 40, desirably at an operational point 46 which indicates a current less than I_{P} but greater than I_{V}. For the purposes of illustration, if voltage source 38 presents around 0.7 volts across voltage reference nodes 36 and 30, then 0.05 of the 0.7 volts may appear across tunnel diode 16 and 0.65 volts may appear across storage capacitor 14.

When transistor 12 is in the off state and cell state node 28 is at a relatively low voltage, memory cell 10 may be characterized as indicating a logic zero memory state. Tunnel diode 16 has a relatively high voltage across its ports 32 and 34, but storage capacitor 14 is storing a relatively low charge. Tunnel diode 16 operates in positive resistance region 44, desirably at a operational point 48 which also indicates a current less than I_{P} but greater than I_{V}. For the purposes of illustration, if voltage source 38 presents around 0.7 volts across voltage reference nodes 36 and 30, then 0.5 of the 0.7 volts may appear across tunnel diode 16 and 0.2 volts may appear across storage capacitor 14.

At operational point 46 a greater voltage appears at storage capacitor 14 than at operational point 48. For that reason, a greater leakage current from cell state node 28 may be experienced at operational point 46 than at operational point 48, and tunnel diode 16 supplies more current at operational point 46 than at operational point 48. Desirably, the peak-to-valley ratio of tunnel diode 16 is as great as possible so that operational points 46 and 48 may be spaced as far below peak current I_{P} and above valley current I_{V} as possible. In addition, the distance at which the current of operational point 46 is below peak current I_{P} is desirably roughly equal to the distance at which the current of operational point 48 is above valley current I_{V} to improve operational reliability.

Those skilled in the art will appreciate that exotic semiconductor processing techniques need not be used to achieve the above-discussed mutual configuration between tunnel diode 16 and storage capacitor 14. Rather, the voltage presented by voltage source 38 can be adjusted as needed to achieve a beneficial balance of leakage and supply currents and to yield reliable operation. If a leakage current from cell state node 28 is closer to the minimum leakage current of I_{V}, then the voltage presented by voltage source 38 may be increased so that operational points 46 and 48 are better balanced between I_{P} and I_{V}. Likewise, if a leakage current from cell state node 28 is closer to the maximum leakage current of I_{P}, then the voltage presented by voltage source 38 may be decreased so that operational points 46 and 48 are better balanced between I_{P} and I_{V}. A beneficial operating range should be achieved when voltage source 38 provides a voltage in the range of 0.5 to 1.5 volts.

Those skilled in the art will appreciate that tunnel diode 16 is primarily designed to supply leakage currents from cell state node 28 when transistor 12 is in the off state. When transistor 12 is in the on state, current flow significantly greater than leakage current is experienced to and from cell state node 28 via bit line 20. The conventional DRAM practice of writing with each read access is desirably continued in connection with memory cell 10 because the act of reading most likely drains any charge from storage capacitor 14.

FIG. 3 shows a cross sectional schematic view of a selected portion of memory cell 10 to illustrate semiconductor processing considerations for memory cell 10. In accordance with one preferred embodiment of the present invention, memory cell 10 is formed on a mono-crystalline silicon substrate 50 having a substantially planar surface 52. Transistor 12 and storage capacitor 14 may be formed in a substantially conventional DRAM manner, with storage capacitor 14 being formed as immediately adjacent to transistor 12 as possible to minimize the area used in forming memory cell 10. In accordance with one embodiment of the present invention, compared to some prior art techniques fewer counterproductive processing techniques need to be employed in an attempt to minimize leakage from storage capacitor 14 because memory cell 10 requires greater than a minimum leakage current I_{V} (FIG. 2) from cell state node 28, and a reduced leakage current may cause leakage current to fall below this minimum.

In the exemplary embodiment depicted in FIG. 3, substrate 50 in the vicinity of memory cell 10 is doped to exhibit a P type conductivity. Transistor 12 includes spaced-apart source and drain regions 54 and 56, each of which are doped to exhibit an N+ type conductivity. An N type conductivity region 58 is formed over a gate oxide layer 60 in the vicinity of a gap 62 between source and drain regions 54 and 56 to form a gate of transistor 12.

Storage capacitor 14 is formed in a trench 64 positioned adjacent to transistor 12. Storage capacitor 14 includes a dielectric region 66 sandwiched between and otherwise adjacent to both substrate 50 and a poly-crystalline silicon (polysilicon) region 68. Polysilicon region 68 is doped to exhibit N+ conductivity, and contacts a vertical side of source region 54 in this example. Desirably, dielectric region 66 is formed from a material or materials which exhibit a dielectric constant greater than 10 and is as thin as practical so that the capacitance exhibited by capacitor 14 is as great as possible given the surface area of substrate 50 occupied by capacitor 14. The use of materials having dielectric constants greater than 10 will tend to cause the leakage current of capacitor 14 to exceed the minimum leakage current I_{V} (FIG. 3) that balances the characteristics of tunnel diode 16 with those of storage capacitor 14. Examples of suitable materials for dielectric region 66 include TiO₂, Ta₂O₅, SrTiO₃, and Si₃N₄, but nothing prevents those skilled in the art from using other suitable materials.

In the exemplary embodiment, an oxide layer 70 is formed over transistor 12 and capacitor 14 prior to the formation of tunnel diode 16. A via 72 is etched through oxide layer 70 down to and exposing surface 52 of substrate 50 over source region 54. Next, a thin layer of a dielectric material 74 is formed within via 72 on surface 52.

Dielectric material 74 serves three purposes. Dielectric material 74 increases the peak-to-valley ratio of tunnel diode 16, forms a barrier which impedes diffusion of the heavy concentrations of dopant away from opposing sides of the tunnel diode 16 semiconductor junction, and reduces leakage current of tunnel diode 16 to that of the storage device. Consequently, a more abrupt semiconductor junction results and a robust tunneling phenomenon is demonstrated. However, the thinner the layer of dielectric material 74 is the better the resulting performance. In one preferred embodiment, a layer of SiO₂ preferably less than 20 Å thick, and more preferably between 4 Å and 16 Å thick, is reliably formed using a simple natural or native oxidation process. After removing the etchant used to form via 72, memory cell 10 may simply be exposed to the atmosphere for a few seconds. However, other materials or other thin dielectric formation techniques known to those skilled in the art may also be used.

After formation of dielectric material 74, polysilicon region 76 is formed within and beyond via 72, and doped to exhibit P+ type conductivity. Polysilicon region 76 may be routed laterally (not shown) so that it can contact V_{CC}. In addition, other vias 78 are formed and then filled with suitable conductive material down to regions 56 and 58 to provide contacts for gate and drain nodes of transistor 12.

Region 54 of transistor 12 corresponds to I/O node 26 of transistor 12, a node of storage capacitor 14, and port 32 (FIG. 1) of tunnel diode 16. In addition, region 54 serves as cell state node 28 for memory cell 10. Tunnel diode 16 results from the semiconductor junction between N+ region 54 and P+ polysilicon region 76. Thus, tunnel diode 16 is formed on I/O node 26 (FIG. 1) of transistor 12 so that it consumes substantially no additional semiconductor surface area beyond the same semiconductor surface area used to form transistor 12 and storage capacitor 14. More specifically, tunnel diode 16 is formed over node 26 of transistor 12 along an imaginary line 80 perpendicular to substantially planar surface 52 of substrate 50 and passing through region 54. Accordingly, the area of semiconductor substrate 50 occupied by memory cell 10 need not expand to accommodate the inclusion of tunnel diode 16. A memory device constructed in accordance with the teaching of the present invention need experience no reduction in bit density due to the inclusion of the present invention. Rather, bit densities may increase due to omission of refresh circuitry and/or a requirement for smaller storage capacitor 14 area achievable when storage capacitor 14 leakage need not be minimized but should exhibit greater than a minimum leakage current.

In summary, the present invention provides an improved semiconductor memory with leakage current compensation. A memory cell configured in accordance with the teaching of the present invention achieves the bit densities of DRAM, but requires little or no refreshing. Since little or no refreshing is required, a memory device configured in accordance with the teaching of the present invention consumes less power and has reduced throughput times. A tunnel diode is provided in the memory cell to supply current lost by leakage. The tunnel diode uses substantially the same semiconductor die area that is used in forming a memory cell transistor and storage capacitor. The memory cell can be fabricated using only routine processing activities in widespread use throughout the semiconductor industry. Moreover, the memory cell readily accommodates capacitors formed using materials having dielectric constants greater than 10, and need not require counterproductive processing techniques performed solely to lessen capacitor leakage.

Although the preferred embodiments of the invention have been illustrated and described in detail, it will be apparent to those skilled in the art that various modifications may be made therein without departing from the spirit of the invention or from the scope of the appended claims. For example, if memory cell 10 is operated so that tunnel diode 16 does not fully compensate for leakage current and memory cell 10 is not a completely refreshless memory cell, beneficial results nevertheless result when tunnel diode 16 partially compensates for leakage current. In this adaptation, memory cell 10 would be only partially refreshless, and control circuitry would still be needed to perform some refresh operations. However, the frequency of refresh operations would be lower than if tunnel diode 16 were omitted and a power savings would nevertheless result. Further, this alternative may permit a greater bit density resulting from the use of smaller storage capacitors. Those skilled in the art will appreciate that a variety of semiconductor structures other than those depicted in FIG. 3 may be substituted herein. For example, while FIG. 3 depicts capacitor 14 formed in a trench, alternates such as planar, stacked, and mound capacitor structures may be substituted. Moreover, those skilled in the art will appreciate that polarities can generally be reversed, and that the voltage, logic state, conductivity type and other polarities discussed above do not impose limitations on the claims set forth below.

What is claimed is:

1. A semiconductor memory cell with leakage current compensation comprising:
a transistor;
a storage capacitor coupled to said transistor; and
a tunnel diode coupled to said transistor and to said storage capacitor, wherein leakage current of said storage capacitor is compensated by current from said tunnel diode.

2. A semiconductor memory cell as claimed in claim 1 wherein said storage capacitor is configured so that said memory cell is volatile.

3. A semiconductor memory cell as claimed in claim 1 wherein said transistor, said storage capacitor, and said tunnel diode are configured to form a refreshless dynamic memory cell.

4. A semiconductor memory cell as claimed in claim 1 wherein said storage capacitor is coupled between said transistor and a first reference voltage node;
said tunnel diode is coupled between said transistor and a second reference voltage node; and
a voltage is presented between said first and second reference voltage nodes.

5. A semiconductor memory cell as claimed in claim 1 wherein:
as voltage across said tunnel diode increases, said tunnel diode respectively exhibits a first positive resistance region, a negative resistance region, and a second positive resistance region;
said tunnel diode is configured to operate in said first positive resistance region while said storage capacitor stores a first charge which represents a first memory state; and
said tunnel diode is configured to operate in said second positive resistance region while said storage capacitor stores a second charge which represents a second memory state.

6. A semiconductor memory cell as claimed in claim 1 wherein:
said transistor, said capacitor, and said tunnel diode couple together at a cell state node;
said transistor exhibits on and off states; and
when said transistor exhibits said off state, current leakage from said cell state node approximately equals current supplied to said cell state node through said tunnel diode.

7. A semiconductor memory cell as claimed in claim 1 wherein said storage capacitor comprises a dielectric material exhibiting a dielectric constant greater than 10.

8. A semiconductor memory cell as claimed in claim 1 wherein:
said tunnel diode exhibits a valley current (I_{V}) when operated at a valley voltage (V_{V}); and
said storage capacitor is configured to exhibit a minimum leakage current greater than said valley current.

9. A semiconductor memory cell as claimed in claim 1 wherein said storage capacitor comprises:
a first conductive region;
a dielectric region adjacent to said first conductive region, said dielectric region being formed from the group consisting essentially of TiO₂, Ta₂O₅, SrTiO₃, and Si₃N₄; and
a second conductive region coupled to said transistor.

10. A semiconductor memory cell as claimed in claim 1 wherein:
a first I/O node of said transistor couples to said storage capacitor and to said tunnel diode;
a control node of said transistor couples to a select line; and
a second I/O node of said transistor couples to a bit line.

11. A semiconductor memory cell as claimed in claim 1 wherein:
said transistor, said storage capacitor, and said tunnel diode are formed on a semiconductor substrate having a substantially planar surface; and
said tunnel diode is formed over a node of said transistor along a line perpendicular to said planar surface and passing through said node of said transistor.

12. A semiconductor memory cell as claimed in claim 1 wherein said tunnel diode is configured so that substantially no additional semiconductor surface area is used to form said tunnel diode beyond the same semiconductor surface area used to form said transistor and said storage capacitor.

13. A semiconductor memory cell as claimed in claim 1 wherein:
said transistor has an I/O node formed as a region which exhibits a first type of conductivity; and
a portion of said region serves as a cathode of said tunnel diode.

14. A semiconductor memory cell as claimed in claim 13 wherein said tunnel diode additionally comprises:
a layer of a dielectric material having a thickness less than 20 Å over said cathode; and
a layer of a second conductivity type material formed over said dielectric material.

15. A semiconductor memory cell as claimed in claim 14 wherein said dielectric material has a thickness between 4 Å and 16 Å.

16. A semiconductor memory cell as claimed in claim 14 wherein:
said I/O node region is formed in a silicon substrate; and
said dielectric material is a native silicon oxide.

17. A semiconductor memory cell as claimed in claim 14 wherein said layer of said second conductivity type material is a polysilicon layer.

18. A semiconductor memory cell with leakage current compensation comprising:
a cell state node;
a transistor having an I/O node corresponding to said cell state node, said transistor exhibiting on and off states;
a storage capacitor having a first conductive region, a dielectric region adjacent to said first conductive region, and a second conductive region adjacent to said dielectric region, said second conductive region corresponding to said cell state node; and
a tunnel diode having a first port corresponding to said cell state node, a dielectric layer, and a second port; wherein
when said transistor exhibits said off state, current leakage from said cell state node approximately equals current supplied to said cell state node through said tunnel diode.

19. A semiconductor memory cell as claimed in claim 18 wherein:
as voltage across said tunnel diode increases, said tunnel diode respectively exhibits a first positive resistance region, a negative resistance region, and a second positive resistance region;
said tunnel diode is configured to operate in said first positive resistance region while said storage capacitor stores a first charge which represents a first memory state; and
said tunnel diode is configured to operate in said second positive resistance region while said storage capacitor stores a second charge which represents a second memory state.

20. A semiconductor memory cell as claimed in claim 18 wherein:
said tunnel diode exhibits a valley current (I_{V}) when operated at a valley voltage (V_{V}); and
said storage capacitor is configured to exhibit a minimum leakage current greater than said valley current.

21. A semiconductor memory cell as claimed in claim 18 wherein said tunnel diode is formed over said I/O node of said transistor so that substantially no additional semiconductor surface area is used to form said tunnel diode beyond the same semiconductor surface area that is used to form said transistor and said storage capacitor.

22. A semiconductor memory cell as claimed in claim 18 wherein said dielectric layer of said tunnel diode has a thickness between 4 Å and 16 Å.

23. A semiconductor memory cell with leakage current compensation comprising:
a transistor having an I/O node forming a cell state node;
a storage capacitor positioned adjacent to said transistor and coupled to said cell state node; and
a tunnel diode coupled to said cell state node and formed on said I/O node, wherein leakage current from said cell state node substantially equals current supplied by said tunnel diode to said cell state node.
